(19) United States
(12) Patent Application Publication
(10) Pub. No.: US 2014/0262149 A1
(43) Pub. Date: Sep. 18, 2014

(54) AIR CIRCULATION IN A SYSTEM

(71) Applicant: TERADYNE, INC., North Reading, MA (US)

(72) Inventor: Brian S. Merrow, Harvard, MA (US)

(73) Assignee: TERADYNE, INC., North Reading, MA (US)

(21) Appl. No.: 13/834,880

(22) Filed: Mar. 15, 2013

(51) Int. Cl. H05K 7/20

(52) U.S. Cl. CPC H05K 7/20136; H05K 7/202
USPC 165/80.2; 165/104.34

(57) ABSTRACT

An example system may include racks that house slots, in which devices may be stored for testing. Cold air from a cold atrium is drawn over the slots and expelled into a warm atrium. The resulting warm air is cooled and then recycled back through the slots to control slot temperature.

### TECHNICAL FIELD

This specification relates generally to ways of circulating air in a system in order to control temperature.

### BACKGROUND

Manufacturers typically test devices, such as storage devices, for compliance with a collection of requirements. Test equipment and techniques exist for testing large numbers of devices serially or in parallel. Manufacturers tend to test large numbers of devices simultaneously. Device testing systems typically include one or more test racks having multiple test slots that receive devices for testing. In some systems, the devices are placed in carriers which are used for loading and unloading the storage devices to and from the test racks.

### SUMMARY

An example system may comprise the following features: slots configured to receive devices to be tested; a device transport mechanism to move devices between a shuttle mechanism and slots; a feeder to provide devices untested devices and to receive tested devices; and a shuttle mechanism to receive an untested device from the feeder and to provide the untested device to the device transport mechanism, and to receive a tested device from the device transport mechanism and to provide the tested device to the feeder. The example system may comprise one or more of the following features, either alone or in combination.

The device transport mechanism may comprise a mast and a rail. The mast may be configured to move along the rail. The shuttle mechanism may comprise a shuttle that is moveable along the rail. The shuttle mechanism may comprise a conveyor. An elevator may receive the untested device from the shuttle and provide the untested to the automation arm, and receive the tested device from the automation arm and present the tested device to the shuttle.

An example system may comprise the following features: slots configured to receive devices to be tested; a servicing device that is, where the servicing device comprises movable parts to move devices into, and out of, the slots; a supplying device to provide devices to be tested and to receive devices that have been tested; and a transportation device that is movable between the supplying device and the servicing device, where the transportation device is configured to receive an untested device from the supplying device and to provide the untested device to the servicing device, and to receive a tested device from the servicing device and to provide the tested device to the supplying device. The example system may comprise one or more of the following features, either alone or in combination.

The movable parts of the servicing device may comprise: an automation arm for moving devices into, and out of, the slots; and an elevator to receive the untested device from the transportation device and to provide the untested device to the automation arm, and to receive the tested device from the automation arm and to present the tested device to the transportation device.

At least two of the following may be movable concurrently: the supplying device, the elevator, the servicing device, and the transportation device. All of the following may be movable concurrently: the supplying device, the elevator, the servicing device, and the transportation device.

The servicing device may comprise two automation arms, one arm on each of two opposite sides of the servicing device. The elevator may be rotatable to reach each of the two automation arms. The servicing device may comprise a linear motor and a non-contact drive mechanism for moving the servicing device along a rail.

An automation arm may be configured to remain docked with a slot while the tested device is moved out of the slot, and the untested device moves into the slot. The elevator may comprise a first holder and a second holder, where the first holder and the second holder are movable relative to the automation in order to receive the tested device and to present the untested device to the slot.

The movable parts of the servicing device may comprise: an automation arm for moving devices into, and out of, the slots, where the automation arm may comprise a pushing element that is operable to contact a device in a slot prior to ejection of the device from the slot. The movable parts of the servicing device may comprise: an elevator to receive the untested device from the transportation device and to present the tested device to the transportation device. The elevator may be offset vertically from, and movable towards, the transportation device to enable transfer of devices between the elevator and the transportation device when the elevator and the transportation device approach contact.

Each slot may comprise an ejection element, where the ejection element is for forcing a tested device out of the slot and into the automation arm.

Another example system may comprise the following features: slots configured to receive devices to be tested; a rail that runs parallel to the slots; a supplying device to provide devices to be tested and to receive devices that have been tested; and a servicing device that is movable along the rail up to the supplying device, where the servicing device comprises movable parts to move devices into, and out of, the slots and to move devices into, and out of, the supplying device. The example system may comprise a magazine configured to contain multiple tested or untested devices, where the servicing device is configured to a move the magazine between the supplying device and the slots.

Another example system may comprise: a first rack of first slots configured to receive devices, where each of at least some of the first slots is for holding a device during testing, where the first rack comprises a front for loading and unloading devices, where the front faces a first area containing cold air, where each of at least some of the first slots comprises an air mover for forcing cold air from the first area over a device and out a first back of the first rack to a second area containing warm air, and where the warm air has a higher temperature than the cold air. The example system may also include: a second rack of second slots configured to receive devices, where each of at least some of the second slots is for holding a device during testing, where the second rack comprises a front for loading and unloading devices, where the front of the second rack faces a third area containing cold air, and where each of at least some of the second slots comprises an air mover for forcing cold air from the third area over a device and out a second back of the second rack to the second area. The example system may also include: a heat exchanger for cooling warm air from the second area to produce cold air; and an air mover for directing the warm air from the second area to the heat exchanger. The example system may comprise one or more of the following features, either alone or in combination.

The heat exchanger is a first heat exchanger and the air mover is a first air mover; the first heat exchanger and the first air mover are associated with the first rack; and the system may comprise a second heat exchanger and a second air mover associated with the second rack. The first heat exchanger and the first air mover may be located at a top of the first rack or at a bottom of the first rack. The second heat exchanger and the second air mover may be located at a top of the second rack or at a bottom of the second rack. Each slot may comprise an internal air mover to force cold air over a device in a corresponding slot.

The third area and the first area may contain automated mechanisms for servicing slots, and the second area may be devoid of at least some of the automated mechanisms contained in the first area and the third area. At least some of the first slots and the second slots may be double-sided. A double-sided slot may be configured for receiving a first device for test from a front of the double-sided slot and for receiving a second device for test from a back of the double-sided slot. Each of the first area, the second area, and the third area may contain automated mechanism for servicing slots. From the first area and the third area, slots are serviced from fronts of the slots, where servicing comprises moving a device into, or out of, a front of a slot; and, from the second area, slots are serviced from backs of the slots, where servicing comprises moving a device into, or out of, a back of a slot. A double-sided slot and a back of a double-sided slot may be serviceable asynchronously, where servicing comprises moving a device into, or out of, the front of the double-sided slot or the back of the double-sided slot.

The air mover and the heat exchanger may be arranged serially in a column of the first rack or a column of the second rack. In the column, the air mover may be closer to the warm air than is the heat exchanger, and the heat exchanger may be closer to cold air than is the air mover. The heat exchanger is a first heat exchanger and the air mover is a first air mover; and the example system may comprise additional heat exchangers and air movers arranged together serially and in columns in both the first rack and the second rack.

Another example system may comprise: a slot to hold a device during testing; a rack to hold the slot; and a negative stiffness isolator that is disposed between the slot to the rack, where the negative stiffness isolator is configured to reduce a natural frequency of vibration of the slot. The example system may comprise one or more of the following features, either alone or in combination.

The negative stiffness isolator may comprise an elastomer having a stiffness and a length that is proportional to the stiffness. The negative stiffness isolator may comprise an element that is in a state of buckling, where the element comprises members that are interconnected at a point such that the element is in the state of buckling at the point. The elastomer may support a weight corresponding to a weight of the slot and the device combined; and the negative stiffness isolator may comprise a spring, where the spring applies a force at the point of buckling that is opposite to a force applied at the point by the weight. The spring may be tunable to vary an amount of force that the spring applies at the point. The spring may be tunable manually or automatically. The spring may be tunable automatically by controlling a motor that affects a stiffness of the spring. The force applied by the spring may be about equal to the force applied by the weight.

The negative stiffness isolator may be configured to drive a natural frequency of vibration of the slot towards zero. The connection to the rack may comprise additional isolators that fit into grooves in the rack, where the additional isolators are connected to a same arm of the rack as the negative stiffness isolators.

The slot may comprise an air mover to blow air over the device, where the air proceeds along an air flow path through the slot, where the slot comprises at least one mostly closed chamber adjacent to the air flow path, and where the at least one chamber is connected to the air flow path via one or more holes to cause a standing pressure wave to resonate in the chamber.

Another example system may comprise: a slot configured to hold a device during testing, where the slot comprises an air mover to blow air over the device, where the air proceeds along an air flow path through the slot, where the slot comprises at least one chamber adjacent to the air flow path, and where the at least one chamber is connected to the air flow path via one or more holes to cause a standing pressure wave to resonate in the chamber. The example system may comprise one or more of the following features, either alone or in combination.

The at least one chamber may comprise multiple chambers with corresponding holes adjacent to the air flow path. The at least one chamber may comprise a single chamber with one or more holes adjacent to the air flow path. The at least one chamber may form a resonator, where the resonator is tunable by varying at least one of: a size of the chambers, a number of chambers, locations of the chambers, a size of the holes, a number of holes, location(s) of the holes, a volume of air in the air flow, a height of the air column in the air flow, and a thickness of the material comprising the chambers.

Another example system may comprise: a slot to hold a device during testing, the slot having a first engagement member; a rack to hold the slot; isolators disposed between the slot and the rack, where the isolators are configured to allow at least some movement of the slot in multiple directions; and an automation arm comprising a second engagement member to interact with the first engagement member. The automation arm may be configured so that interaction of the first engagement member and second engagement causes movement of the slot into alignment with the automation arm such that the alignment permits transfer of the device between the slot and the automation arm.

Another example system may comprise: a slot to hold a device during testing, where the slot has hooks; a rack to hold the slot, which has channels therein; isolators interfacing the slot to the rack, where the isolators are in the channels and allow at least some movement of the slot in multiple directions; and an automation arm comprising structure to coarsely align to the slot and comprising a gripper to interact with the hooks following coarse alignment, where the gripper comprises fingers for interacting with the hooks causing movement of the slot into alignment with the automation arm, and where the alignment permits transfer of the device between the slot and the automation arm. The example system may comprise one or more of the following features, either alone or in combination.

The isolators may comprise elastic members that are flexible and mounted in the channels. The fingers may be movable by the automation arm to draw the slot into alignment with the automation arm. The structure to coarsely align to the slot may comprise one or more pins for aligning to one or more corresponding holes on the slot. There may be a sensor to detect coarse alignment and to initiate interaction of the fingers and hooks. A finger may be movably mounted within a space that is curved towards the finger at a top of the space and at a bottom of the space. The finger may be movably mounted such that movement of the finger within the space causes movement of the finger in two directions to pull the slot towards the automation arm. The multiple directions may be three directions.

The automation arm may be a two-sided automation arm, which comprises a gripper. The automation may comprise areas for accommodating devices that are horizontally adjacent, where each such area comprises a gripper. The automation may comprise areas for accommodating devices that are horizontally adjacent, where each such area comprises a common gripper. The automation may comprise areas for accommodating devices that are vertically adjacent, where each such area comprises a gripper.

Another example system may comprise: a slot configured to hold a device during testing, where the device has a front that faces out of the slot and sides, and where the slot comprises: cam locks, clamps, and gates. The clamps may be controllable to apply force to the sides of the device. The gates may be controllable to block or to unblock the front of the device. Each of the cam locks may be configured to control, with a single rotational motion, a corresponding clamp and gate. The example system may comprise one or more of the following features, either alone or in combination.

The clamps may be operable to provide clamping force in a direction that is at an angle to a clamping force provided by the gates. The angle may be about 90°.

The example system may comprise an automation arm comprising keys that mate to corresponding cam locks, where each key, when mated to a corresponding cam lock, is rotatable effect the single rotational motion. Each cam lock may be configured to rotate a first angular distance to control a corresponding gate and a second angular distance to control a corresponding clamp. The first angular distance may be less than the second angular distance in a case where the corresponding gate and corresponding clamp are to be closed, and the first angular distance may be greater than the second angular distance in a case where the corresponding gate and corresponding clamp are to be open.

The example system may comprise a conductive thermal heating device. The cam lock may be configured to control, with the single rotational motion, contact between the device under test in the slot and the conductive thermal heating device. The example system may comprise an automation arm comprising a pushing element to contact the device in the slot during insertion and removal of the device. A slot may comprise hooks to interact with corresponding fingers on an automation arm when the slot is docked with the automation arm.

Another example system may comprise: slots configured to receive devices, where each of at least some of the slots is for holding a device during testing, and where each of the at least some slots comprises a processing device to exchange information using a wireless protocol; and a control center to exchange the information wirelessly with processing devices in the slots. The example system may comprise one or more of the following features, either alone or in combination.

The control center may comprise one or more computing devices configured to communicate wirelessly with at least some of the processing devices in the slots. The processing device may comprise at least one of a microprocessor, a microcontroller, an ASIC and an FPGA. The wireless protocol may comprise at least one of Bluetooth (over IEEE 802.15.1), ultra-wideband (UWB, over IEEE 802.15.3), ZigBee (over IEEE 802.15.4), and Wi-Fi (over IEEE 802.11). The wireless protocol may be only ZigBee (over IEEE 802.15.4).

The information may comprise one or more of test status, test yield, and test parametrics. The information may comprise firmware for the device held in the slot for test. The information may comprise a test script containing operations for testing for the device held in the slot for test.

The example system may comprise: a rail that runs parallel to the slots; a mast that is movable along the rail, where the mast comprises movable parts to move devices into, and out of, the slots; a feeder to provide devices to be tested and to receive devices that have been tested; and a shuttle that is movable along the rail between the feeder and the mast, where the shuttle is configured to receive an untested device from the feeder and to provide the untested device to the mast, and to receive a tested device from the mast and to provide the tested device to the feeder. The control center may be configured to communicate wirelessly with at least one of the mast, the feeder, and the shuttle.

The movable parts of the mast may comprise: an automation arm for moving devices into, and out of, the slots; and an elevator to receive the untested device from the shuttle and to provide the untested device to the automation arm, and to receive the tested device from the automation arm and to present the tested device to the shuttle. The control center may be configured to communicate wirelessly with at least one of the automation arm and the elevator.

Any two or more of the features described in this specification, including in this summary section, can be combined to form implementations not specifically described herein.

The systems and techniques described herein, or portions thereof, can be implemented as/controlled by a computer program product that includes instructions that are stored on one or more non-transitory machine-readable storage media, and that are executable on one or more processing devices to control (e.g., coordinate) the operations described herein. The systems and techniques described herein, or portions thereof, can be implemented as an apparatus, method, or electronic system that can include one or more processing devices and memory to store executable instructions to implement various operations.

The details of one or more implementations are set forth in the accompanying drawings and the description below. Other features, objects, and advantages will be apparent from the description and drawings, and from the claims.

### DESCRIPTION OF THE DRAWINGS

FIG. 1A is a perspective view of a front of an example test system that includes a rack, a mast, a shuttle and an elevator.

FIG. 1B is a perspective close-up view of the shuttle and the elevator shown in the example system of FIG. 1.

FIGS. 2 to 15 are perspective views that depict an example operation of an example test system of the type shown in FIG. 1.

FIGS. 16 to 37 are perspective close-up views showing the operation of example elements that may be used in the system of FIGS. 2 to 15.

FIG. 38 is a perspective view of an alternative implementation of the example test system described herein.

FIGS. 39 and 40 are perspective views of racks in an example test system.

FIG. 41 is a side view of example racks in a test system.

FIG. 42 is a perspective view of example slots in a test system.

FIG. 43 is a perspective cut-away view of an example slot in a test system.

FIG. 44 is an exploded view of components of an example rack in a test system.

FIG. 45 is a perspective side view of a warm atrium in a test system.

FIG. 46 is a perspective view of an example of a two-sided slot.

FIG. 47 is a perspective view of an example of a rack containing air movers and heat exchangers mounted in a column of the rack.

FIG. 48 is a perspective view of an example slot.

FIG. 49 is a perspective, front view of an example negative stiffness isolator.

FIG. 50 is a perspective, back view of an example negative stiffness isolator, with the rack to which the isolator is mounted shown as transparent.

FIG. 51 is a plot illustrating the natural frequency of a system.

FIG. 52 is a bottom perspective view of an internal portion of an example slot.

FIG. 53 is a perspective view of an example slot containing hooks for use in docking with a corresponding automation arm.

FIG. 54 is a perspective view of an automation arm containing a gripper having fingers for docking with hooks of a corresponding slot.

FIG. 55 is a perspective view of a hook in a slot in an open position.

FIG. 56 is a perspective view of a hook in a slot in a closed position.

FIG. 57, comprised of FIGS. 57A, 57B and 57C, are side views showing interaction of a slot hook and gripper finger during slot/arm docking.

FIGS. 58 to 60 are perspective views of different configurations of automation arms and corresponding grippers.

FIG. 61 is a front view of a slot containing cam locks and closed ejector clamps, referred to herein as “gates”.

FIG. 62 is a perspective view of keys on an automation arm that mates to corresponding slot cam locks.

FIG. 63 is a perspective close-up view of a key.

FIG. 64 is a top view of a slot containing a device, and showing how side clamps and gates interact with the slot.

FIG. 65 is a close-up perspective view of interaction between an automation arm key and a slot cam lock.

FIG. 66, comprised of FIGS. 66A and 66B, are close-up perspective views showing opening of a gate by turning a cam lock.

FIGS. 67 to 69 are top views of portions of the same slot and automation arm, which illustrate a sequence of operations for inserting a device into a slot and removing the device from the slot.

FIG. 70 is an angular chart showing the various rotational positions θ1, θ2 and θ3 of a cam lock that is on the left of a slot when facing the slot.

FIG. 71 is a perspective view of a test system and control center, which are configured to exchange at least some communications wirelessly.

### DETAILED DESCRIPTION

Described herein are example systems for testing devices, including, but not limited to, storage devices. A storage device includes, but is not limited to, hard disk drives, solid state drives, memory devices, and any storage device that benefits from asynchronous testing. A hard disk drive is generally a non-volatile storage device that stores digitally encoded data on rapidly rotating platters with magnetic surfaces. A solid-state drive (SSD) is generally a data storage device that uses solid-state memory to store persistent data. An SSD using SRAM or DRAM (instead of flash memory) is often called a RAM-drive. The term solid-state generally distinguishes solid-state electronics from electromechanical devices.

Although the example systems described herein focus on testing storage devices, the systems may be used in testing any type of device. For examples, in this context, a device may include, but is not limited to, biological samples, semiconductor devices, mechanical assemblies, and so forth.

### Parallel Operations

Referring FIG. 1A, an example storage device testing system 100 may include multiple test racks 101 (only one depicted) and automated elements to move storage devices between a storage device feeder and the test racks. The test racks may be arranged in horizontal rows and vertical columns, and mounted in one or more chassis. As shown in FIG. 1A, each test rack 101 generally includes a chassis 102. Chassis 102 can be constructed from a plurality of structural members (e.g., formed sheet metal, extruded aluminum, steel tubing, and/or composite members) that are fastened together and that together define receptacles for corresponding test slots or packs of test slots. Each rack houses multiple test slots. Different ones of the test slots may be used for performing the same or different types of tests and/or for testing the same or different types of storage devices.

In an example implementation, a rack 101 is served by a mast. In this example, “servicing” includes moving untested storage devices into test slots in the rack, and moving tested storage devices out of test slots in the rack. An example of a mast 105 used to service test rack 101 is shown in FIG. 1A.

In the example of FIG. 1A, mast 105 includes magnets (not shown) and a linear motor (not shown) that enable mast 105 to move horizontally along a track 106. The combination of a linear motor and magnets may eliminate the need for belts or other mechanics that can complicate the construction of the system. However, in other implementations, belts or other mechanics may be used, at least in part, to move the mast along the track.

In some implementations, track 106 may run substantially parallel to the front (see, e.g., FIGS. 1A and 1B) of rack 101. In this context, the “front” of a rack is the side of the rack from which storage devices can be loaded into, and removed from, slots in the rack. In other implementations, storage devices can be loaded into, and removed from, both sides (back and front) of a rack. In such implementations, there may be a track on each side (e.g., front and back) of the rack, with each such track serviced by a separate mast.

In some implementations, mast 105 includes an automation arm 107 for removing storage device from, and inserting storage devices into, corresponding test slots in the rack. In an example implementation, automation arm 107 is a structure that supports a storage device, and that projects from the mast to a slot during docking (engaging) with a slot, and that retracts towards the mast when disengaging from the slot. Automation arm 107 is movable vertically along mast 105 to align to a slot to be serviced. In this regard, as noted above, mast 105 moves horizontally along track 106. The combination of the mast's horizontal motion and the automation arm's vertical motion enables servicing of any slot in a test rack. At least part of the horizontal and vertical motions may be concurrent.

The automation arm is configured to dock with a corresponding slot during loading of an untested device and unloading of a tested device. As explained in more detail below, when docked, a tested device in a slot may be moved, from the slot, to automation arm 107, to an elevator 109. In some implementations, the elevator may be considered part of the mast. An untested device may be moved from elevator 109, to automation arm 107, to the slot for testing. In some implementations, the automation arm remains docked with the slot for a whole time during transfer of a tested device out of a slot, and of an untested device into that same slot for testing. This, however, need not be the case in all system implementations.

Referring to FIG. 2, in some implementations, a mast 201 contains two automation arms 202, 203, with one on each side of the mast. Each automation arm is configured to service a corresponding rack. So, for example, automation arm 202 services rack 204. Automation arm 203 services another rack (not shown) facing rack 204. In the examples of FIGS. 1A and 2, the automation arm is not rotatable relative to the mast. This is why there are two automation arms—one for each side of the mast. In other implementations, a single automation arm may be used, and that automation arm may be rotatable to service racks on each side of the mast. In some implementations, the automation arm can have multiple degrees of movement. In some implementations, the automation arm can be fixed to the mast to serve two sides of the mast or pivotal to serve the two sides.

Referring to FIG. 1B, elevator 109 is movable vertically along mast 105 between the location of a shuttle 110 (described below) and the location of the automation arms. Elevator 109 is configured to receive a storage device to be tested from the shuttle, to move that storage device vertically upwards along the mast to reach an automation arm, to receive a tested storage device from the automation arm, and to move that tested storage device vertically downwards to reach the shuttle. Mechanisms (described below) at each automation arm and at the shuttle are configured to move a storage device to/from corresponding mechanisms on elevator 109. In the implementation of FIG. 1A, elevator 109 is rotatable relative to mast 105 to service both of its automation arms. For example, referring to FIG. 2, the elevator may or may not rotate in one direction to service automation arm 202, and in the opposite direction to service automation arm 203. In this context, servicing includes, but is not limited to, exchanging tested and untested storage devices with an automation arm.

In this regard, in some implementations storage devices in system 100 are tested asynchronously. That is, in such implementations, there is no synchronization among testing of storage devices in the system. As a result of this asynchronicity, there is no correlation between testing in corresponding slots on different racks facing the automation arms. Accordingly, in these example implementations, there is no disadvantage to allowing one elevator to service a single side of the mast at a time, e.g., to service a single automation arm.

Shuttle 110 is an automated device that is movable horizontally along a track between a feeder and mast 105. Shuttle 110 is configured to move untested storage devices from the feeder to elevator 109, and to move tested storage devices from elevator 109 to the feeder. Advantageously, shuttle 110 is operable so that an untested device is carried from the feeder to the elevator, and then a tested device is carried from the elevator on the shuttle's return trip back to the feeder. This can increase testing throughput, since no shuttle trip is wasted.

Shuttle 110 includes an automation arm 112 for holding tested and untested storage devices, and for interacting with elevator 109. As described below, automation arm 112 is controllable to retrieve an untested storage device from the feeder, to transfer the untested storage device to elevator 109, to receive a tested storage device from elevator 109, and to transfer the tested storage device to the feeder. In the implementation of FIG. 2, the shuttle automation arm is rotatable relative to the mast. As such, shuttle 205 is rotatable so that it faces either mast 201 or feeder 208 (see FIGS. 3 and 4). In some implementations, as described in an example below, the shuttle's automation arm need not rotate in this manner.

Referring to FIG. 2, an example feeder 208 is configured to move untested storage devices to the shuttle, and to accept tested storage devices from the shuttle. Untested storage devices may be loaded manually or automatically into feeder 208, and tested storage devices may be unloaded manually or automatically from feeder 208. For example, devices may pass through conduits 213 and down/up towers 214 to a loading/unloading area 215. In some implementations, the shuttle may move left to right along another track (not shown) that is parallel to the feeders so as to align with different towers. In other implementations, as described below, there may be multiple shuttles, along multiple tracks, which access different loading/unloading areas of different towers of feeder 208.

FIGS. 2 to 15 show an example operation of example a test system 200 that includes features of the type described above with respect to FIGS. 1A and 1B. In FIG. 2, shuttle 205 is at a loading/unloading area of feeder 208. There, shuttle 205 receives an untested storage device. As shown in FIG. 3, automation arm 216 rotates from the loading/unloading area toward mast 201. This may be done as shuttle 205 moves along track 217 towards mast 201 or it may be done beforehand. Concurrently, in FIG. 3, automation arm 202 of mast 201 docks with a slot 219 in rack 220 containing a storage device that has been tested.

In FIG. 4, tested storage device 221 is ejected to automation arm 202, while untested storage device 222 remains in elevator 224 ready to be inserted into slot 219. FIG. 4 also shows automation arm 216 of shuttle 205 fully rotated towards mast 201 and traveling towards mast 201. Meanwhile, referring to FIG. 5, tested storage device 221 continues ejection into automation arm 202. Eventually, tested storage device 221 is fully ejected into automation 202, leaving slot 219 empty and ready to receive untested storage device 222.

Referring to FIG. 6, elevator 224 shifts sideways to move tested storage device 221 out of the insertion path of slot 219 (e.g., out of automation arm 202), and to move untested storage device 222 into the insertion path of slot 219 (e.g., into place in automation arm 202). In FIG. 7, untested storage device 222 is in automation arm 202, and ready for insertion into slot 219. In FIG. 8, untested storage device is inserted (e.g., pushed) by automation arm 202 into slot 219. Meanwhile, elevator 224 moves downward vertically, towards the shuttle 205, which awaits with an untested storage device 223 to be loaded into elevator 224. The tested storage device in elevator may likewise be loaded into the shuttle.

In FIG. 9, untested storage device 222 is almost completely inserted into slot 219. Meanwhile, elevator 224, which is holding tested storage device 221, rotates towards automation arm 216 of shuttle 205. Elevator 224 hands-off tested storage device 221 to automation arm 216 of shuttle 205, as shown in FIG. 10. In some implementations, at about the same time, elevator 224 receives the untested storage device 223 from automation arm 216 of shuttle 205. Automation arm 202 of mast 201 disengages from the previously-serviced slot, and moves up or down in a direction of a next slot to be serviced (e.g., towards the slot in which untested storage device 222 is to be inserted).

Referring to FIG. 11, automation arm 202 of mast 201 is disengaged from slot 219. Also, elevator 224 has possession of untested storage device 223 and shuttle 205 has possession of tested storage device 221. In FIG. 11, shuttle 205 is rotating away from mast 201, towards feeder 208, in order to hand-off tested storage device 221 to feeder 208 and pick-up an untested storage device at the loading/unloading station. Meanwhile, referring to FIGS. 11, 12 and 13, mast 201 moves along track 217 towards the next slot to be serviced. This movement may occur at the same time as movement of automation arm 202, 203 vertically along mast 201, until the automation arm reaches the next slot to be serviced. Meanwhile, elevator 224 rotates towards mast 201 to a position so that it can move upwards along mast 201 toward automation arm 202 (or arm 203 if the slot being serviced faces arm 203). The shuttle 205, at this time, deposits the tested storage device 221 in feeder 208 and picks-up an untested storage device. FIG. 14 shows further movement of elevator 224 and automation arm 202 along mast 201.

In FIG. 14, elevator 224 moves the untested storage device toward the new slot, e.g., upwards along mast 201. Meanwhile, in FIG. 15, shuttle 205 picks-up an untested storage device to be brought to elevator 224. Thereafter, the process described above is repeated to load/unload storage devices in a test slot.

In some implementations, all or part of the following operations (a), (b), (c), (d) may occur in parallel: (a) shuttle operation—transfer a tested device from the mast towards the feeder, (b) elevator operation—transfer an untested device from the shuttle towards the automation arm, (c) automation arm operation—remove tested device from a slot, and (d) feeder operation—advance a device to be tested in its input queue.

In some implementations, all or part of the following operations (e), (f), (g), (h) may occur in parallel: (e) shuttle operation—transfer an untested device from the feeder towards the mast, (f) elevator operation—transfer a tested device from the automation arm towards the shuttle, (g) automation arm operation—insert untested device in a slot, and (h) feeder operation—sort tested devices for output.

In some implementations, different combinations of operations (a) through (h) may be performed in parallel or sequentially.

By employing parallel (e.g., concurrent) operation of various automated parts, as described above, it may be possible to increase the number of storage devices serviced by the test system (system throughput). Similarly, the time it takes to unload a tested device and load an untested device (cycle time) may be decreased. In some implementations, average cycle time can be about 10 seconds. However, the cycle time is dependent upon many different factors, including the geometry of the system and the speed at which the various components operate.

FIGS. 16 to 37 show close-up views of example elements that may be incorporated into a system like that described with respect to FIGS. 2 to 15. In the example system of FIGS. 16 to 37, the shuttle may not rotate to meet elevator in the manner described above. Other than that, the operation is the same as that described above with respect to FIGS. 2 to 15.

Referring to FIG. 16, elevator 301 moves down to the base of mast 304 holding a tested storage device 306. Meanwhile, shuttle 302 approaches elevator 301 holding an untested storage device 307. When the two meet, as shown in FIG. 17, arm 309 of elevator 301 is offset vertically from shuttle 302. In this example, the automation arm of the shuttle is above the elevator relative to a ground plane.

Referring to FIG. 17, shuttle 302 and elevator 301 align to enable elevator 301 to drop-off a tested storage device 306 with shuttle 302, and to pick-up an untested storage device 307 from shuttle 302. As shown in FIG. 17, shuttle 302 is slightly above elevator 301. Shuttle 302 includes two receptacles 310, 311, one for a providing an untested storage device and one for receiving a tested storage device. Elevator 301 includes two holders 312, 313, which align to corresponding receptacles 310, 311 on the shuttle. As shown in FIG. 17, elevator 301 lifts holders 312, 313 slightly upward to dock with corresponding receptacles 310, 311 of shuttle 302. This upward movement causes tested storage device 306 to move upwards into receptacle 310 and causes holder 313 to come into contact with untested storage device 307 in receptacle 311 of the shuttle.

Referring to FIG. 18, with the appropriate storage devices 306, 307 aligned to/in the appropriate receptacles 310, 311, elevator 301 activates its side clamping mechanism to grab untested storage device 307 from the shuttle, and deactivates its side clamping mechanism, leaving tested storage device 306 to be held in place in the shuttle. Thereafter, referring to FIG. 19, elevator 301, holding untested storage device 307, moves downward relative to shuttle 302, leaving shuttle 302 holding tested storage device 306. As shown in FIG. 20, shuttle 302 proceeds, with the tested storage device 306, to the feeder, along track 320, as described above. Meanwhile, elevator 301 proceeds to bring untested storage device 307 to the automation arm (not shown) of mast 304, as described above.

Referring to FIG. 21, elevator 301 moves untested storage device 307 upwards along mast 304 in the direction of arrow 321. As shown in FIG. 21, a tested storage device 322 is already resident in slot 323. Automation arm 324 of mast 304 is aligned horizontally with slot 323 in FIG. 21; however, automation arm 324 is not yet docked to slot 323. In FIG. 22, automation arm 324 projects toward slot 323 and docks to slot 323. For example, automation arm 324 may project outwardly towards the slot. In some implementations, keys on automation arm 324 may mate to corresponding locks on slot 323 to perform the docking. In other implementations, other docking mechanisms may be used. As shown, empty holder 312 of elevator 301 aligns with the opening 327 of automation arm 324 that is for receiving a tested storage device from a test slot. Holder 313, containing untested storage device 307, is offset from opening 327.

Referring to FIG. 23, elevator 301 moves holder 312 upwards (arrow 328) so that it docks with automation arm 324 at opening 327. This docking is performed so that holder 312 can receive a tested storage device 322 from slot 323. In some implementations, automation arm 324 includes a push element (referred to as a “pusher”). The pusher is operable to hold a tested storage device in place in test slot 323 when clamps and other mechanisms in the test slot are released. The pusher is also operable to move an untested device into the test slot.

More specifically, in some implementations, each test slot includes an ejection mechanism (referred to as an “ejector”). In some implementations, the ejector is a spring-loaded device that pushes against the storage device in the slot. In some implementations, the ejector is an electronically controllable member, whose force may be set in response to one or more commands. In any case, absent structure holding the storage device in the slot, the ejector may push against the storage device, thereby causing it to be ejected from the slot.

In some implementations, side clamps and a front gate (also referred to as “ejector clamps”—not shown) hold the storage device in the slot during testing. That is, the side clamps provide inward pressure holding the storage device in the slot, and the front gate, which is located in front of the storage device, prevents movement of the storage device out of the slot. When the side clamps and front gate are disengaged, the result is that the ejector forces the storage device out of the slot. The pusher therefore engages the storage device prior to the side clamps and front gate disengaging. The pusher may provide force that is opposite to, but typically less than, that provided by the ejector. Accordingly, when the side clamps and front gate are disengaged, the result is that ejector pushes the storage device out of the slot, but the pusher provides enough opposite force to ensure a controlled ejection. Operation of the pusher may be controlled electronically so that the pusher retracts while still providing appropriate force to prevent abrupt ejection of the storage device. As a result, the possibility of harm to the storage device resulting from abrupt ejection is reduced.

Referring to FIG. 24, pusher 330, which may be part of the automation arm, moves into contact with tested storage device 322 prior to its ejection. Thereafter, in FIG. 25, the side clamps 331 of the test slot are disengaged. In some implementations, the front gate is disengaged prior to the pusher making contact with the storage device. In other implementations, the front gate may be disengaged slightly before disengaging the side clamps.

Following disengaging of the side clamps, as shown in FIG. 26, pusher 330 retracts (arrow 331) as ejector 332 forces tested storage device 322 out of slot 323 and into the automation arm. Automation arm 324 clamps the tested storage device to reduce the chances that it will fall out of the automation arm during the unloading process. In FIG. 27, tested storage device 322 is in place in arm 324/elevator 301. Thereafter, in FIG. 28, the automation arm clamps disengage, and elevator clamps 334 fasten the storage device to holder 312.

In FIG. 29, elevator 301 moves downward along mast 304, away from automation arm 324. As a result, tested storage device 322, fastened to holder 312, moves downward as well, thereby disengaging from the automation arm.

In FIG. 30, elevator 301 slides sideways so that untested storage device 307 is underneath, and aligns to, opening 327 in the automation arm. Thereafter, in FIG. 31, elevator 301 moves holder 313, which contains untested storage device 307, upwards so that holder 313 docks with automation arm 324 at opening 327. This is done as a precursor to loading untested storage device 307 into slot 323.

Referring to FIG. 32, clamps on automation arm clamp (arrow 341) storage device 307, and clamps on elevator 301 disengage (arrow 342) from storage device 307. This allows automation arm 324 to control movement of storage device 307 into test slot 323. In FIG. 33, pusher 330 forces (arrow 341) storage device 307 part-way into test slot 323, and the automation arm clamps are disengaged (arrow 342). In FIG. 34, pusher 330 positions the untested storage device 307 fully into test slot 323. In response to receipt of the storage device, side clamps on the test slot are engaged (arrow 345). A front gate may also be engaged. Both the side clamps and front gate prevent the test slot from ejecting. Control of the front gate and side clamps may be performed in the manner described below.

Referring to FIG. 35, pusher 330 retracts (arrow 346) back into automation arm 324, leaving untested storage device 307 in test slot 323. In FIG. 36, elevator 301, which holds tested storage device 322, moves downward along mast 304 to meet the shuttle. In FIG. 37, automation arm 324 disengages from test slot 323. Thereafter, processing may proceed in a manner described above with respect to FIGS. 2 to 15.

In the example implementations described above, a single shuttle is used and a single mast is used. However, in some implementations, multiple shuttles and/or masts may be used. For example, referring to FIG. 38, a test system may include three tracks 401, 402, 403, three shuttles 405, 406, 407, and three mast 410, 411, 412. Mast 410 may service one segment of test slots; mast 411 may service another segment of test slots; and mast 412 may service yet another segment of test slots. For example, mast 410 may service a first third of test slots; mast 411 may service a second third of test slots; and mast 412 may service the final third of test slots. In such an implementation, shuttle 405 may service mast 410; shuttle 406 may service mast 411; and shuttle 407 may service mast 412. Shuttle 405 may run along the same track as the masts to reach only mast 410. Shuttle 406 may run along track 401 to reach mast 411; and shuttle 407 may run along track 403 to reach mast 412. In other implementations, there may be two masts and two shuttles or more than three masts and three shuttles per pair of test racks.

In some implementations, there may be more than one mast and/or shuttle of per track. For example, such masts and shuttles may operate from opposite ends of a rack of slots, thereby servicing different portions of the rack. In some implementations, there may be a single shuttle on a track, which can service multiple masts operating on a single, adjacent track.

In other example implementations, the test system need not include a shuttle. For example, the mast may move along a track to the point of the feeder. There, the mast may pick-up a magazine or cartridge containing multiple untested storage devices. The mast may then operate to load each storage device from the magazine into a test slot, and to load tested storage devices into the magazine. When the magazine is devoid of untested devices, and loaded with tested devices, the mast may drop-off the magazine at the feeder, pick-up a new magazine containing untested storage devices, and repeat the process.

In another example implementation, the shuttle is replaced by a conveyor, which is configured to transport one or more devices between the feeder and the mast. For example, the conveyor may move the devices between the feeder and the mast. At the feeder, the conveyor may pick-up a magazine containing multiple untested storage devices. The conveyor may then transport the magazine to the mast. The mast may then operate to load each storage device from the magazine into a test slot, and to load tested storage devices into the magazine. When the magazine is devoid of untested devices, and loaded with tested devices, the conveyor may drop-off the magazine with the feeder, pick-up a new magazine containing untested storage devices from the feeder, and repeat the process.

In some implementations, the conveyor may move a single device. In some implementations, there may be multiple conveyers of the type described herein operating on the same or adjacent tracks between feeder(s) and mast(s).

In general, the example test system described herein may have the following advantages concerning cycle time: (1) separation of transportation from manipulation: device transportation may occur in parallel with device manipulation; (2) the transportation device (e.g., shuttle) and the manipulation device (e.g., mast) may share the same moving tracks; (3) the transportation device (shuttle) may be light and fast, and thus does not contribute significantly to system cycle time. Furthermore, as the shuttle moves in parallel with the mast, the shuttle does not add considerable extra time to the overall system cycle time.

In some implementations, the elevator may not be used on the mast. Instead, the automation arm may contain structure, similar to that described herein, to interact with the shuttle to move tested devices from the automation arm to the shuttle, and to move untested devices from the shuttle to the automation arm.

### Air Movement

FIG. 39 shows two racks of test slots of the type described above arranged side-by-side. Although only two test racks are shown in FIG. 39, a test system may include any number of test racks arranged side-by-side, as shown in FIG. 40. In the example implementation of FIG. 38, a mast, of the type shown in FIG. 1, runs along a track between racks 501 and 502 to service slots therein as described herein. The mast and the track are not shown in FIG. 39; however, FIG. 41 is a side view of racks 501, 502, showing mast 504, track 505, and shuttle 506. In some implementations, there may be shuttles on two sides of a mast.

Area 508 between racks 501 and 502 is referred to as a cold atrium. Area 509 outside of rack 501 and area 510 outside of rack 502 are referred to as warm atriums. In implementations like that shown in FIG. 40, there are additional racks adjacent to racks 501 and 502, making at least some of warm atriums semi-enclosed spaces, and at least some of the cold atriums semi-enclosed spaces. In this regard, each atrium may be an open, enclosed, or semi-enclosed space.

Generally, air in a cold atrium is maintained at a lower temperature than air in a warm atrium. For example, in some implementations, air in each cold atrium is at about 15° C. and air in each warm atrium is at about 40° C. In some implementations, the air temperature in the warm and cold atriums is within prescribed ranges of 40° C. and 15° C., respectively. In some implementations, the air temperatures in the warm and cold atriums may be different than 40° C. and/or 15° C., respectively. The relative air temperatures may vary, e.g., in accordance with system usage and requirements.

During testing, cold air from a cold atrium 508 is drawn through the test slots, and over the devices under test. This is done in order to control the temperature of devices during test. Due at least in part to device operation in the slots, the temperature of the cold air passing over the devices rises. The resulting warm air is then expelled into a warm atrium 510. Air from each warm atrium is then drawn through a corresponding cooling mechanism, and expelled to the cold atrium. From there, the resulting cold air is re-cycled. In the example implementation of FIG. 39, there are one or more cooling mechanisms 512 and corresponding air movers 513 at the top of each rack and at the bottom of each rack. There may be different arrangements and/or mechanisms used in other implementations.

Air flow between the cold and warm atriums is depicted by the arrows shown in FIG. 39. More specifically, warm air 515 exits test slots 516. This warm air 515 is drawn by air movers 513 (e.g., fans) through corresponding cooling mechanisms 512, resulting in cold air 518. Cold air 518 is output towards the center of the rack (either upwards or downwards, as shown). From there, air movers in the slots draw the cold air through the slots, resulting in output warm air. This process/air flow cycle continually repeats to thereby maintain devices under test and/or other electronics a slot within an acceptable temperature range.

In some implementations, slots in a rack are organized as packs. Each pack may hold multiple slots and is mounted in a rack. An example pack 520 is shown in FIG. 42. The example pack 520 includes air movers 521 (e.g., blowers) in each slot, which force air over devices in the slots during testing.

In this regard, FIG. 43 shows a cross-section of a slot 525 which includes an air mover 526. In FIG. 43, cold air from cold atrium 527 is drawn, by air mover 526, through the slot. The cold air passes over device 528 (in this example, a storage device) under test in the slot. The cold air warms as it absorbs heat from the device, and is expelled as warm air into warm atrium 529.

Referring to FIG. 41, in some implementations, devices are loaded into slots in the rack only from the cold atrium. In these implementations, the side of the rack from which devices are loaded is referred to as the “front” of the rack. Accordingly, using this convention, the front of the rack faces the cold atrium and the back of the rack faces the warm atrium.

FIG. 44 shows an exploded view of components of an example implementation of a rack 501 (or 502) depicted from the front of the rack. Rack 501 includes packs 530 (also referred to as modular bays) containing slots in which devices are inserted for test. The packs are held together by structural members 531, which may be of the type described above. In this example, there are two heat exchanging plenums 512a and 512b, which are examples of the cooling mechanisms described above. One plenum 512a is mounted near or to the base of the rack and another plenum 512b is mounted near or to the top of the rack. As explained above, plenums 512a and 512b receive warm air from the warm atrium, and cool the air (e.g., by removing heat from the warm air using, e.g., a heat exchanger), and expel cold air into the cold atrium.

In some implementations, each air plenum outputs cold air, which moves towards the center of a rack. For example, air may move from the top of a rack towards the center or from the bottom of a rack towards the center. In this regard, air movers create a high pressure area at the plenum exhaust, and the movement of the air through the slots causes a relatively lower air pressure towards the middle of the racks, so the air appropriately diffuses. Air movers in the slots draw this cold air from the cold atrium over devices in the slots.

In some implementations, the warm atrium may include one or more air mover boxes 513a, 513b at the top and/or bottom of the racks. An example interior of a warm atrium is shown in FIG. 45, including air mover boxes 533. Each such air mover box may include one or more fans or other air movement mechanisms. The air movers in the warm atrium draw warm air from the slots towards/into corresponding plenums. The plenums receive this warm air and cool it, as described above. Although only two air mover boxes and corresponding plenums per rack are shown in FIG. 44, there may be different numbers and configurations of air mover boxes and plenums per rack in other implementations.

In some implementations, a grating may be installed over and above air mover boxes at the bottom of the rack, thereby forming a walkway for a technician to access the back of each slot via the warm atrium. Accordingly, the technician may service a slot through the back of a slot, without requiring an interruption in movement of the automated mechanisms (mast, shuttle, etc.) at the front of the rack.

In the examples described above, each test slot holds a single device. For example, as shown in FIG. 43, slot 525 holds a single device 528 to test, which may be loaded by the mast automation arm from the cold atrium into the front of the slot. In other implementations, however, a slot may be double-sided. That is, the slot may hold two devices, which may be tested asynchronously. One device may be loaded into a single slot from the cold atrium as described above, and another device may be loaded into the same single slot from the warm atrium. That is, one device may be loaded into the slot from the front of the slot and another device may be loaded into the slot from the back of the slot. The two devices typically face out of the slot—one towards the front and one towards the back. The two devices may be serviced by different masts (one in the warm atrium and one in the cold atrium) and, therefore, may be tested asynchronously. That is, there need be no coordination of testing between the two devices, and each device may be replaced/removed with little (or without any) dependence upon when and/or whether the other device in the same slot is replaced and/or removed.

FIG. 46 shows an example of a two-sided slot 540. As shown, slot 540 can accommodate a device (e.g., a storage device) loaded from either side 541 or 542. Side 541 may face a cold atrium and side 542 may face a warm atrium, making it possible to service the same slot from both atriums. In some implementations, the devices in the same slot are not physically or electrically connected together in a way that would cause testing, removal or replacement of one device to have a significant (or any) effect on testing, removal or replacement of the other device. Also, in some implementations, testing performed on two devices in the same slot is not coordinated. Accordingly, the test system may operate asynchronously or mostly asynchronously vis-à-vis the two devices in the same slot.

Implementations that use a two-sided slot will typically employ a mast, shuttle, and other automated mechanisms of the type described herein (e.g., FIGS. 1 to 38) in both the warm atriums and the cold atriums. Accordingly, in such implementations, there may be less opportunity for a technician to service slots from the warm atrium. However, the increase in throughput resulting from double-sided servicing may make-up for this decrease in serviceability.

In some implementations, the plenums and air movers may be located in a column of each rack instead of at the rack top and bottom. An example implementation in which this is the case is shown in FIG. 47. For example, plenums 545 may be located on the side of the rack facing the warm atrium and air movers 546 may be adjacent to the plenums on the side of the rack facing the cold atrium, or vice versa. A column may service one rack, two racks, or more than two racks. When arranged in this manner, the air movers force the warm air from the warm atrium, through corresponding plenums, resulting in cold air that is expelled into the cold atrium. Because the plenums and air movers are arranged in a column, there is less need to circulate the air from top to bottom of the racks, as in implementations where the plenums and air movers are located at the rack top and bottoms. Furthermore, additional slots can be added at tops and bottoms of the racks to make-up for space taken-up in the columns.

### Vibration Reduction

Slots may be mounted on racks using isolators that are configured to reduce the amount and/or frequencies of vibrations transmitted between the slots and the rack. This can be beneficial when testing devices that have moving parts, and whose movement can result in vibrations that can be transmitted to the rack and thus to other slots in the rack and/or parts that are sensitive to externally-induced vibration. For example, a disk drive includes a spinning magnetic disk. Movement of the disk causes vibrations that can be transmitted to the slot which, in turn, can be transmitted to the rack and to other slots. Vibrations, such as these, can adversely affect testing performed in other slots.

Different types of isolators may be used to reduce transmission of vibrations among slots in a rack. In example implementations, the isolators include, but are not limited to, low stiffness gel, rubber grommets, and a negative stiffness isolator. For example, the low stiffness gel may be incorporated between the device and the slot to reduce vibrations in a low frequency range. Rubber grommets, as described below, may be used to reduce vibration in a mid-frequency range. A negative stiffness isolator, as described below may be used to reduce vibrations in a high-frequency range. Generally speaking, frequencies in the low frequency range, the mid-frequency range, and the high frequency range may vary in accordance with various system parameters. In an example, implementation the low frequency range is lower than the mid-frequency range and the mid-frequency range is lower than the high frequency range. The system may also include a dampening system, as described below, to reduce acoustic vibrations (noise).

FIG. 48 shows an example of a slot 600 that may be used in a test system of the type described herein. Slot 600 includes, among other things, a tray 602. Tray 602 holds a device 604 under test. The slot includes structure to mount slot 600 to rack 606. In some implementations, slot 600 is mounted to rack 606 using isolators, such as grommets 608. Grommets 608 are rubber in some implementations; however, grommets 608 may include any appropriate vibration-reducing (e.g., elastic) material. In some implementations, each grommet 608 is fixed to a corresponding arm 609 of the slot frame. Grommets 608 fit into corresponding grooves 610 in rack 606. Grommets 608 are movable within those grooves and, furthermore, are flexible. As such, grommets 608 aid in reducing transmission of vibrations from the slot to the rack. That is, at least some vibrations may be absorbed through movement of the grommets in the slots and by the relative softness or pliability of the grommets.

The slot may also be mounted to frame 606 using negative stiffness isolators 612. FIG. 49 shows a close-up view of a negative stiffness isolator 612a. FIG. 50 shows the same negative stiffness isolator 612a from its back and with rack 606 transparent. FIGS. 49 and 50 also show a grommet 608a, of the type described above, which is connected to a same arm 609a of the slot as the negative stiffness isolator.

Negative stiffness isolator 612a includes an elastomer 614 mounted in series with a negative stiffness element 615. The elastomer 614 is suspended from arm 609a on the slot, and is mechanically connected to apply downward force (weight) to the negative stiffness element. The weight supported by the elastomer, and thus applied to the negative stiffness element, is equal to the weight of the slot plus the weight of any device in the slot. The weight is applied at about the point 616 where the negative stiffness element is in a state of buckling, as described below.

In this regard, negative stiffness element 615 leverages an unstable linkage member 617 in a stage of buckling. Springs 618, at either end of the member apply inward force that is translated, through elements 620, to member 617. This force places member 617 in a state of buckling. Member 617 is in buckling at pin joint 616, e.g., the point where its two components 617a, 617b link together. The linkage may be implemented via a pin or other connection mechanism.

With the compressive force (e.g., weight) applied to member 617 by elastomer 614, linkage member 617 becomes unstable. Member 617 is made stable via a spring 624 that applies upward force at point 616 to produces a negligible dynamic stiffness. That is, an upward force is applied by spring 624, which counteracts the weight supported by elastomer 614. With the correct calibration of spring 624, member 617 reaches its critical buckling load. By tuning the stiffness of spring 624 against the buckling load (in this case, the weight), the result is a vibration system with a dynamic stiffness that approaches (although does not necessarily reach) zero. This near-zero dynamic stiffness drives the natural frequency of system vibration towards zero.

FIG. 51 may be used to explain why it is beneficial to drive the natural frequency of the system towards zero. Specifically, FIG. 51 is a plot showing frequency versus transmissibility of vibrations. The natural frequency of the system is the spike at point 625. At vibrational frequencies to the left of point 625, the system amplifies the vibrations. At vibrational frequencies to the right of point 625, the system attenuates (e.g., reduces or dampens) the vibrations. Accordingly, the closer that point 625 (the natural frequency) gets to zero, the fewer frequencies will be amplified and the more frequencies will be attenuated. This is because more frequencies are to the right of point 625 than to the left of point 625.

As noted above, in a real system, it may be difficult to achieve a zero natural frequency. To further reduce the natural frequency, the length (L) of elastomer 614 may be increased which, in turn, results in lower dynamic stiffness. In some implementations, elastomer is about 20 mm long; however, the length of an elastomer may vary from system-to-system depending on numerous factors, such as the weight, required buckling force, desired natural frequency, and so forth.

In some implementations, spring 624 is tuned manually to provide a force that is about equal to, and opposite of, the force applied by the combined weight of the slot and the device in the slot. In some implementations, spring 624 may be tuned automatically. For example, spring 624 may be tuned using a computer-controlled motor, which can vary the stiffness in accordance with commands input to a test computer. In other implementations, a tunable element other than a spring (e.g., a piston) may be used to provide the opposite force for the negative stiffness element.

In addition to the negative stiffness element, the system may use dampening to reduce acoustic noise (vibrations) at high frequencies. In an example implementation, a resonator may be formed at a front end of an air mover assembly in a slot. The resonator may be formed by creating chambers with the slot, and exposing those chambers to the air flow via holes that are adjacent to the air flow.

More specifically, as explained above, air from the cold atrium moves through the slot, over a device in the slot, and out to a warm atrium. An air mover may draw the air from the cold atrium into the slot by creating a region of lower air pressure caused by its air flow. The air flow through the slot may flow over holes to chambers of air. This causes formation of a standing pressure waive at a particular frequency. In some implementations, the chambers 635 of air are below the slot and the holes 636 are underneath the air flow, as shown in FIG. 52, which depicts an underside portion of the slot. The underside, and thus the chambers, may be sealed with a base (not shown in FIG. 52). In other implementations, the chambers of air may be above the slot, on sides of the slot, or elsewhere.

The standing pressure wave created by the resonator acts to counter acoustic vibrations in the air flow. For example, in some implementations, the standing pressure wave may cancel-out, or substantially cancel-out, acoustic vibrations in the air flow. In some implementations, the frequency of the standing pressure wave is centered around about 2500 Hertz (Hz) with attenuation around 1000 Hz. In other implementations, the frequency of the standing pressure wave may be different, and the attenuation frequency may also be different.

In this regard, the example resonator described herein may be tuned by varying one or more of the following: the size of the chambers, the number of chambers, the location of the chambers, the size of the holes, the number of holes, the location of the holes, the volume of air in the air flow, the height of the air column in the air flow, the thickness of the material comprising the chambers, and so forth.

In some implementations, like that shown in FIG. 52, the resonator includes a number of chambers, each with its own hole. In other implementations, the number of holes may not correspond to the number of chambers. For example, there may be a single chamber with multiple holes. In some implementations, like that shown in FIG. 52, the chambers are triangular in shape. In other implementations, different shapes may be used. In some implementations, the resonator may be formed at a location other than at the front end of an air mover assembly. For example, the resonator may be formed at the back end of an air mover assembly, mid-way through the slot, or at any other appropriate location.

In some implementations, acoustic vibrations in the air flow may also be reduced by using larger air movers in the slots than are required to achieve an appropriate air flow volume, rate, etc., and running the air movers slower than their full speed, e.g., at half-speed. This can reduce the overall acoustic noise in the system and reduce high-frequency vibrations picked-up by a device in a slot.

### Alignment

Devices under test, such as storage devices, may be susceptible to shock and vibration during operation and testing. Shock and vibration events can also occur, for example, when a storage device is inserted or removed from a test slot. In this regard, during testing, devices are frequently swapped-out for different devices while the surrounding devices are operating or being tested. In some cases, it can be difficult to insert or remove a device from a test slot without causing the test slot to move a chassis of the test rack. An impact produced in this way can create a shock or vibration event that is transmitted to adjacent devices in other test slots, which degrades the isolation scheme of the test rack. This problem can be amplified by the high density of the test rack, as the test slots can be located in close proximity to one another to conserve space.

In some examples, additional shock or vibration events can be created while a device to be tested is pushed against or pulled away from one or more electrical connecting elements located in the test slot. In order for the device to mate or un-mate with the electrical connecting elements, some degree of force is exerted on the device. This force can be greater than the force require to insert the device into the test slot, and can have vibrational consequences.

One way to reduce the likelihood of causing shock or vibration events is to use precision automation when aligning a device to a test slot. In some cases, however, the location of the test slot may change with loading and with temperature, as the isolators associated with the test slot change shape under stress or with temperature. Precision automation to counteract these effects can unduly increase the cost of the test system.

The example test system described herein can reduce the need for precision automation, as described above. More specifically, in some implementations, each test slot is mounted to a rack (or pack in the rack) using elastic isolators. For example, as shown in FIG. 48, test slot 600 is mounted to grooves 610 in rack 606 using grommets 608. Such a mounting configuration allows at least some movement of the slot in multiple (e.g., Cartesian X, Y and Z) directions. Effectively, such a mounting allows the test slot to float, to an extent, on the rack, meaning that the test slot may be movable on the rack while still being mounted to the rack. While such movement is beneficial for vibration isolation, it can result in various test slots being misaligned, in different ways, to a corresponding automation arm.

Accordingly, in some implementations, if the test slot is out of alignment with the automation arm of a mast during a docking process, the automation arm may grab the test slot and force the test slot into an alignment sufficient to allow the test slot and the automation arm to dock, and thereby load/unload devices in the test slot. The force applied by the automation arm may move the test slot within the rack, and into an alignment, without removing the test slot from the rack. This can be done without transmitting significant vibrations to the test rack.

In an example implementation, the test slot includes hooks and the automation arm includes a gripper. FIG. 53 shows examples of hooks 700 that may be included on test slot 701, and FIG. 54 shows an example of a gripper 702 that may be included on automation arm 704. Gripper 702 is configured to catch, and mate to, hooks 700 even if the gripper and the hooks are not in fine alignment. Rather, there may be only a coarse alignment between the gripper and the hooks. In some implementations, as shown, gripper 702 includes two fingers that grab corresponding hooks exposed on the slot during slot/automation arm docking. Generally, the fingers and the hooks may be referred to as engagement members.

FIG. 55 shows finger 702a of gripper 702 prior to interaction with a corresponding hook. FIG. 56 shows finger 702a and hook 700a mated during docking of the automation arm and slot. Each finger is mounted in a cam configuration, so that when it is pulled back by the automation arm in one direction (in order to pull the slot into alignment with the automation arm), the pulling action results in two-directional motion of each finger.

More specifically, as shown in FIG. 57, each finger (e.g., finger 702b) includes a channel 705 that is curved towards the finger 702b at its top portion 706 and at its bottom portion 707. In response to force on a structure mounted in this channel, a finger moves in a roundward motion to grab the slot hook and, when pulled back towards the automation arm, to pull the slot together with (including into alignment with) the automation arm. As shown in FIG. 57A, finger 702b is in an open position relative to hook 700b. Finger 702b is pulled in the direction of arrow 707 by the automation arm to thereby move, in a camming motion, in the direction of both arrows 709 and 708 (FIG. 57B). This causes finger 702b to come into alignment with hook 700b. Further motion of finger 702b in the direction of arrow 707 pulls hook 700b (and the rest of the slot attached to hook 700b) into alignment with, and into a position for docking with, the automation arm connected to finger 702b. In some implementations, the docking fingers pull the hooks with a force of 35 pounds (lbs)+1-2 lbs; however, different forces may be applied in other implementations.

Control mechanisms in the automation arm may be used to control movement of the gripper. In some implementations, the gripper may be controlled so that both fingers are pulled in concert. In other implementations, the fingers may be independently controllable. Chamfered pins 710 may be included on automation arm 704 (FIG. 54) for use in detecting an initial coarse alignment to the slot. For example, the pins may align to corresponding holes in the slot. This coarse alignment may be detected by a sensor (not shown) in the automation arm or in communication with a controller of the automation arm. Upon detecting this coarse alignment, the automation arm may control the gripper in the manner described above to pull the slot into alignment with the automation arm. For example, the automation arm may pull the fingers of the gripper inward (toward the automation arm) so as to pull the slot into alignment.

As a result of the pulling motion performed by the gripper, the slot moves into alignment with the automation arm. Because the slot is movably mounted on flexible isolators, the amount of vibrations resulting from alignment can be reduced. For example, the slot may be gathered to the automation arm, thereby maintaining benefits of the slot's vibration isolation system during loading and docking.

In the example implementations described above, the automation arm is a two-sided arm of the type shown in FIGS. 1 to 11, with each side having a corresponding gripper. In other implementations, the automation arm may be of the type show in FIGS. 58 to 60. For example, in FIG. 58, there are two side-by-side automation arm areas, each with a separate gripper 720, 721. Each automation arm area is for holding a device for loading/unloading to/from the test system. Such an automation arm may be used to load/unload horizontally adjacent slots concurrently. In FIG. 59, there are two side-by-side automation arm areas, with a common gripper 722. In FIG. 60, there are two vertically-stacked automation arm areas, each with a separate gripper 724, 725. Such an automation arm may be used to load/unload vertically adjacent slots concurrently. In some implementations, automation arms of the type shown in FIGS. 58 to 60 may be on each side of a mast.

The docking process initiated by the hooks and gripper results in alignment and mating of keys on the automation arm to corresponding locks on the slot. The keys and locks may be used to actuate mechanisms to hold a device under test in the slot, and to allow the device to be removed from the slot. These features are described in more detail below.

### In-Slot Clamping

Docking operations are performed prior to inserting a device into a test slot or removing a device from a test slot. Prior to device insertion/removal, as described above, a gripper grabs a slot and aligns the slot to an automation arm. The slot may include mechanisms to hold, or clamp, a device under test in the slot. In some implementations, those mechanisms may include a slot clamp, which is referred to simply as a “clamp” or “side clamp”, and a slot ejector clamp, which is referred to as a “gate”. As described in more detail below, the side clamps hold the device in the slot by applying pressure at an angle (e.g., about a right angle) to the direction at which the device is loaded/unloaded to/from the slot. The gate is movable in front of a device in the slot, thereby preventing movement of the device out of the slot. To move a device out of the slot, the gate is opened (e.g., moved away from the front of the slot) and pressure on the clamps is relieved. The side clamps and the gate may be operated using a single mechanical control and in response to a single motion, as described below.

FIG. 61 shows a front view of a slot 800 holding a device 801 under test. As shown in FIG. 61, slot 800 includes gates 802, which are movable in front of device 801, thereby preventing device 801's ejection from the slot (the ejection would be in the Z-direction—out of the page, in this example). The side clamps are not visible in FIG. 61, but apply force to device 801 in the direction of arrows 804.

Cam locks 805 control operation of the side clamps and gates 802 in response to a single turning motion. In some implementations, as described below, cam locks 805 may be turned part-way to activate the gates, and then further to activate the clamps, or vice versa. For example, to close the clamps and the gates, the cam locks may be turned inwardly towards the center of device 801, and to open the clamps and the gates, the cam locks may be turned outwardly away from the center of device 801, or vice versa. Regardless, the same cam lock and the same turning motion may control both opening and a single corresponding side clamp and gate. As described below, the amount of angular rotation of the cam locks (relative to a reference) dictates whether the side clamps and/or the gate are closed or opened.

Cam locks 805 physically connect to corresponding keys on the automation arm that docks with the slot. FIG. 62 shows an example of keys 806, which are part of a feature on automation arm 808, that mate to the cam locks. FIG. 63 shows a close-up view of one of key 806a. The projections 807 on the keys mate to corresponding grooves 809 on the cam locks. When mated with the cam locks, the keys are rotatable by the automation arm to control rotation of the cam locks and thus to control the gates and the clamps as described herein.

FIG. 64 is a top view showing gates 802 and clamps 810. Arrows 811 indicate the direction of movement of clamps 810. FIG. 65 is a perspective view showing a gate 802a and a clamp 810a, both in the closed position. As shown in FIG. 65, key 806a from automation arm 808 mates to lock 805a on slot 800. The key is rotatable to control motion of gate 802a to its open or closed position, and to control, via axle 814, rotation of clamp 810a to its open or closed position. Rotation of key 806a may be controlled using, e.g., electronics on the automation arm. FIG. 66 shows movement of gate 802a from a closed position (FIG. 66A) (in front of device 801) to an open position (FIG. 66B) (not in front of device 801). As show, in this example, to open gate 802a (and also the side clamps), lock 805a is rotated in the direction of arrow 818 (by a corresponding mated key). To close gate 802a (and also a corresponding side clamp) lock 805a is rotated opposite to the direction of arrow 818.

FIGS. 67 to 69 show an example operational sequence for insertion or removal of a device into a test slot from/to an automation arm. In FIGS. 67 to 69, the gripper 820 of automation arm 808 is engaged with hooks 821 of slot 800. The key on the automation arm is omitted from the figures. Reference is also made to FIG. 70, which is an angular chart showing the various rotational positions θ1, θ2 and θ3 of cam lock 805b. A similar, but opposite chart (not shown) describes the rotation of cam lock 805a, and its effect on gate 802a and 810a. That is, cam lock 805b rotates clockwise to control closing of gate 802b and clamp 810b. By contrast, cam lock 805a rotates counter-clockwise to control closing of gate 802a and clamp 810a at equal, and opposite, angular positions from those shown in FIG. 70.

In some implementations, to insert a device 801 from automation arm 808 into slot 800, a pusher 824 on automation arm 808 moves from position Y1 (FIG. 69) to position Y3 (FIG. 68). Cam lock 805b rotates from position 81, in which the side clamps and gates are open, to position 82, in which the side clamps remain open but in which the gate 802b corresponding to cam lock 805b is closed. Concurrently, cam lock 805a is rotated in the opposite direction to cam lock 805b and at the same angular distance, leaving the side clamps open, but closing the gate 802a corresponding to cam lock 805a. Thereafter, pusher 824 may be retracted to position Y2 (FIG. 67) or Y1. Cam lock 805b is then rotated to position 83, thereby closing the side clamp 810b corresponding to cam lock 805b. Concurrently, cam lock 805a is rotated in the opposite direction to cam lock 805b and at the same angular distance, thereby also closing the side clamp 810a corresponding to cam lock 805a At this rotational angle (θ3), both the gates are also closed, leaving the device held firmly in the slot.

In some implementations, θ1 is 0°±10°, θ2 is 100°±10°, and θ3 is 220°±60°. In other implementations, θ1, θ2 and θ3 may have different values and/or may be rotated 180° relative to the graph of FIG. 70, or by some other value.

In some implementations, to remove a device 801 from slot 800 and accept it into automation arm 808, pusher 824 moves from position Y1 to position Y2. Cam lock 805b is then rotated from position θ3 to position θ2. Pusher 824 is then moved to position Y3. Cam lock 805b is then moved from position θ2 to position θ1, and pusher 824 is moved to position Y1. At each time, cam lock 805a is rotated an angular distance that is equal, but opposite, to the angular distance rotated by cam lock 805b. The values of θ1, θ2 and θ3, and the states of the clamps and gates at those angular rotations may the same as described above.

Thus, to summarize, a single rotatable motion may cause two sequential clamping motions, one in the X dimension and one in the Y dimension. That is, the cam lock is rotated resulting in clamping the device in the slot in the X dimension (e.g., lowering of the gate), and then the cam lock is further rotated resulting in clamping the device in the Y dimension (e.g., actuation of the side clamps). Opposite rotation of the cam lock causes, in turn, release of the side clamps followed by lifting of the gate, as described above.

The operations described above, including movement of the pusher and rotation of the keys/cam locks may be controlled by electronics in the test system. The electronics may include one or more computing devices, and may be local to the automation arm, remote from the automation arm, or a combination of local to and remote from the automation arm. For example, the operations may be directed by a computing device used to coordinate test operations.

In some implementations, the single action of the rotary cam locks, which clamps the device in X and Y dimension, causes conductive thermal heating devices to be applied the sides of the devices for test process thermal conditioning. For example, the conductive thermal heating devices may be moved by the same axle that moves the side clamps, and may contact the sides of the device, e.g., at the same time as the side clamps contact the device or at a different time. For example, the conductive thermal heating devices may contact the sides of the device at an angular position 84, which may be before or after θ1, θ2 and θ3, between θ1 and θ2, or between θ2 and θ3.

The test systems described herein are not limited to use with clamps and gates as described above, nor to the numbers of clamps and gates shown. Any appropriate number of claims and/or gates may be used. Likewise, the order of operations described above may vary in other implementations and/or one or more operations may be omitted in other implementations.

### Wireless Communications

In some implementations, a test system may include a control center, from which one or more test engineers may direct testing of devices in the slots. FIG. 71 shows an example control center 900 and test system 901. Test system 901 may include or more of the features described with respect to FIGS. 1 to 70, or it may have different features. In this example, test system 901 includes slots for holding devices under test, and automation for moving devices into, and out of, the slots. In other implementations, the test sites may not be slots, but rather other areas or structures at which a test may be conducted.

Each slot 903 of test system 901 may include one or more processing devices 905. In some implementations, a processing device may include, but is not limited to, a microcontroller, a microprocessor, an application-specific integrated circuit (ASIC), a field-programmable gate array (FPGA), a network processor, and/or any other type of logic and/or circuitry capable of receiving commands, processing data, and providing an output. In some implementations, a processing device in each slot is also capable of providing and/or routing power to the slot, including to a device under test in the slot and to other circuit elements in the slot.

Each processing device may be configured (e.g., programmed) to communicate with a device under test in the slot and with other elements of the slot, such as the slot air mover, clamps in the slot, and so forth. For example, each processing device may monitor operations of a device in the slot during testing (including test responses), and report test results or other information back to the control center. In some implementations, each processing device may be configured to communicate wirelessly with the control center.

Examples of wireless protocols that may be used by the processing devices and control center for communication include, but are not limited to, Bluetooth (over IEEE 802.15.1), ultra-wideband (UWB, over IEEE 802.15.3), ZigBee (over IEEE 802.15.4), and Wi-Fi (over IEEE 802.11). Cellular wireless protocols may also be used for wireless communication between the processing devices and the control center. Examples of cellular wireless protocols that may be used by the processing devices and control center for communication include, but are not limited to, 3G, 4G, LTE, CDMA, CDMA2000, EV-DO, FDMA, GAN, GPRS, GSM, HCSD, HSDPA, iDEN, Mobitex, NMT, PCS, PDC, PHS, TAGS, TDMA, TD-SCDMA, UMTS, WCDMA, WiDEN, and WiMAX. Combinations of two or more of the protocols listed herein, or others not listed herein, may also be used to implement wireless connections between the control center and processing devices in the slots.

Use of wireless communication between the control center and processing devices in the slots can reduce the number of wired connections used in the test system. This can reduce system cost and system complexity. For example, wireless communication reduces the number of cables used in the system, thereby reducing the need for vibration isolation of such cables.

Within each slot, there may be wired and/or wired connections between a processing device, a device under test, and various elements of the slot that are controlled by, or communicate with, the processing device. In some implementations, as noted, there may be intra-slot wireless communications, e.g., communications between a processing device and elements in the slot. For example, a device under test may communicate wirelessly to a processing device also in the slot. The intra-slot wireless protocol may be the same wireless protocol used for communication between the processing device and control center, or a different wireless protocol may be used for intra-slot communication and for communication between the processing device and control center.

In some implementations, wireless communications between processing devices in the slots and the control center may be direct. That is, such communications may originate with the control center and be addressed directly to a processing device, or such communications may originate with a processing device and be addressed to the control center. In some implementations, the wireless communications may go through a router or hub in a communication path between the processing devices and the control center. The router or hub may include one or more wired or wireless communication paths. For example, in some implementations, there may be a communications hub for each test rack, through which communications to/from processing devices in the rack are routed.

In some implementations, as described above, there may be a single (one) processing device per slot. In other implementations, a single processing device may serve multiple slots. For example, in some implementations, a single processing device may service a pack, a rack, or other grouping of slots.

The communications to/from each processing device may include, but are not limited to, data representing/for testing status, yield, parametrics, test scripts, and device firmware. For example, testing status may indicate whether testing is ongoing or completed, whether the device under test has passed or failed one or more tests and which tests were passed or failed, whether the device under test meets the requirements of particular users (as defined, e.g., by those users), and so forth. Testing yield may indicate a percentage of times a device under test passed a test or failed a test, a percentage of devices under test that passed or failed a test, a bin into which a device under test should be placed following testing (e.g., a highest quality device, an average quality device, a lowest quality device), and so forth. Testing parametrics may identify particular test performance and related data. For example, for a disk drive under test, parametrics may identify a non-repeatable run-out track pitch, a position error signal, and so forth.

In some implementations, test scripts may include instructions and/or machine-executable code for performing one or more test operations on a device held in a slot for test. The test scripts may be executable by a processing device, and may include, among other things, test protocols and information specifying how test data is to be handled or passed to the control center.

In some implementations, a device under test in a slot may be programmed wirelessly from the control center (via a processing device in the slot), either in response to a test condition or not. For example, as noted, device firmware may be communicated wirelessly from the control center to a processing device in the slot. The processing device may then program the device under test in the slot using that firmware. In some implementations, the processing devices themselves may be programmed wirelessly by the control center.

Referring to FIG. 71, control center 900 may include a computing device 909. Computing device 909 may include one or more digital computers, examples of which include, but are not limited to, laptops, desktops, workstations, personal digital assistants, servers, blade servers, mainframes, and other appropriate computing devices. Computing device 909 may also include various forms of mobile devices, examples of which include, but are not limited to, personal digital assistants, cellular telephones, smartphones, and other similar computing devices. The components described herein, their connections and relationships, and their functions, are meant to be examples only, and are not meant to limit implementations of the technology described and/or claimed herein.

Computing device 909 includes appropriate features, such as one or more wireless cards, that enable computing device 909 to communicate wirelessly with the processing devices in the test system slots in the manner described herein. Computing device 909 (or other devices directed by computing device 909) may also control various other features of the example test system described herein, such as the feeder(s), the mast(s), the shuttle(s), and so forth.

Not all communications between computing device 909 and various other features of the test system need be wireless. For example, test system 901 may include wireless communications between computing device 909 and processing devices in the slots, and wired communications to other features of the system (e.g., the feeder(s), the mast(s), the shuttle(s), and so forth. In some implementations, communications between computing device 909 and all features of the system may be wireless or at least partly wireless. In some implementations, communications to/from the slots may be a combination of wired and wireless communications.

### IMPLEMENTATIONS

While this specification describes example implementations related to “testing” and a “test system,” the systems described herein are equally applicable to implementations directed towards burn-in, manufacturing, incubation, or storage, or any implementation which would benefit from asynchronous processing, temperature control, and/or vibration management.

Testing performed by the example test system described herein, which includes controlling (e.g., coordinating movement of) various automated elements to operate in the manner described herein or otherwise, may be implemented using hardware or a combination of hardware and software. For example, a test system like the ones described herein may include various controllers and/or processing devices located at various points in the system to control operation of the automated elements. A central computer (not shown) may coordinate operation among the various controllers or processing devices. The central computer, controllers, and processing devices may execute various software routines to effect control and coordination of the various automated elements.

In this regard, testing of storage devices in a system of the type described herein may be controlled by a computer, e.g., by sending signals to and from one or more wired and/or wireless connections to each test slot. The testing can be controlled, at least in part, using one or more computer program products, e.g., one or more computer program tangibly embodied in one or more information carriers, such as one or more non-transitory machine-readable media, for execution by, or to control the operation of, one or more data processing apparatus, e.g., a programmable processor, a computer, multiple computers, and/or programmable logic components.

A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a network.

Actions associated with implementing all or part of the testing can be performed by one or more programmable processors executing one or more computer programs to perform the functions described herein. All or part of the testing can be implemented using special purpose logic circuitry, e.g., an FPGA (field programmable gate array) and/or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer (including a server) include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, e.g., magnetic, magneto-optical disks, or optical disks. Machine-readable storage media suitable for embodying computer program instructions and data include all forms of non-volatile storage area, including by way of example, semiconductor storage area devices, e.g., EPROM, EEPROM, and flash storage area devices; magnetic disks, e.g., internal hard disks or removable disks; magneto-optical disks; and CD-ROM and DVD-ROM disks.

Although the example test systems described herein are used to test storage devices, the example test systems may be used to test any type of device.

Any “electrical connection” as used herein may imply a direct physical connection or a connection that includes intervening components but that nevertheless allows electrical signals to flow between connected components. Any “connection” involving electrical circuitry mentioned herein, unless stated otherwise, is an electrical connection and not necessarily a direct physical connection regardless of whether the word “electrical” is used to modify “connection”.

Elements of different implementations described herein may be combined to form other embodiments not specifically set forth above. Elements may be left out of the structures described herein without adversely affecting their operation. Furthermore, various separate elements may be combined into one or more individual elements to perform the functions described herein.

What is claimed is:

1. A system comprising:
a first rack of first slots configured to receive devices, each of at least some of the first slots for holding a device during testing, the first rack comprising a front for loading and unloading devices, the front facing a first area containing cold air, each of at least some of the first slots comprising an air mover for forcing cold air from the first area over a device and out a first back of the first rack to a second area containing warm air, the warm air having a higher temperature than the cold air;
a second rack of second slots configured to receive devices, each of at least some of the second slots for holding a device during testing, the second rack comprising a front for loading and unloading devices, the front of the second rack facing a third area containing cold air, each of at least some of the second slots comprising an air mover for forcing cold air from the third area over a device and out a second back of the second rack to the second area;
a heat exchanger for cooling warm air from the second area to produce cold air; and
an air mover for directing the warm air from the second area to the heat exchanger.

2. The system of claim 1, wherein the heat exchanger is a first heat exchanger and the air mover is a first air mover;
wherein the first heat exchanger and the first air mover are associated with the first rack; and
wherein the system comprises a second heat exchanger and a second air mover associated with the second rack.

3. The system of claim 2, wherein the first heat exchanger and the first air mover are located at a top of the first rack or at a bottom of the first rack; and
wherein the second heat exchanger and the second air mover are located at a top of the second rack or at a bottom of the second rack.

4. The system of claim 1, wherein each slot comprises an internal air mover to force cold air over a device in a corresponding slot.

5. The system of claim 1, wherein the third area and the first area contain automated mechanisms for servicing slots, the second area being devoid of at least some of the automated mechanisms contained in the first area and the third area.

6. The system of claim 1, wherein at least some of the first slots and the second slots are double-sided, a double-sided slot being configured for receiving a first device for test from a front of the double-sided slot and for receiving a second device for test from a back of the double-sided slot.

7. The system of claim 6, wherein each of the first area, the second area, and the third area contains automated mechanism for servicing slots;
wherein, from the first area and the third area, slots are serviced from fronts of the slots, where servicing comprises moving a device into, or out of, a front of a slot; and
wherein, from the second area, slots are serviced from backs of the slots, where servicing comprises moving a device into, or out of, a back of a slot.

8. The system of claim 6, wherein a front of a double-sided slot and a back of a double-sided slot are serviceable asynchronously, where servicing comprises moving a device into, or out of, the front of the double-sided slot or the back of the double-sided slot.

9. The system of claim 1, wherein the air mover and the heat exchanger are arranged serially in a column of the first rack or a column of the second rack.

10. The system of claim 1, wherein, in the column, the air mover is closer to the warm air than is the heat exchanger, and the heat exchanger is closer to cold air than is the air mover.

11. The system of claim 1, wherein the heat exchanger is a first heat exchanger and the air mover is a first air mover; and
wherein the system comprises additional heat exchangers and air movers arranged together serially and in columns in both the first rack and the second rack.

12. A method comprising:
a first rack of first slots receiving devices, each of at least some of the first slots holding a device during testing, the first rack comprising a front for loading and unloading devices, the front facing a first area containing cold air, each of at least some of the first slots comprising an air mover for forcing cold air from the first area over a device and out a first back of the first rack to a second area containing warm air, the warm air having a higher temperature than the cold air;
a second rack of second slots receiving devices, each of at least some of the second slots holding a device during testing, the second rack comprising a front for loading and unloading devices, the front of the second rack facing a third area containing cold air, each of at least some of the second slots comprising an air mover for forcing cold air from the third area over a device and out a second back of the second rack to the second area;
a heat exchanger cooling warm air from the second area to produce cold air; and
an air mover directing the warm air from the second area to the heat exchanger.

13. The method of claim 12, wherein the heat exchanger is a first heat exchanger and the air mover is a first air mover;
wherein the first heat exchanger and the first air mover are associated with the first rack; and
wherein the method comprises a second heat exchanger and a second air mover associated with the second rack.

14. The method of claim 13, wherein the first heat exchanger and the first air mover are located at a top of the first rack or at a bottom of the first rack; and
wherein the second heat exchanger and the second air mover are located at a top of the second rack or at a bottom of the second rack.

15. The method of claim 12, wherein each slot comprises an internal air mover forcing cold air over a device in a corresponding slot.

16. The method of claim 12, wherein the third area and the first area contain automated mechanisms servicing slots, the second area being devoid of at least some of the automated mechanisms contained in the first area and the third area.

17. The method of claim 12, wherein at least some of the first slots and the second slots are double-sided, a double-sided slot receiving a first device for test from a front of the double-sided slot and receiving a second device for test from a back of the double-sided slot.

18. The method of claim 17, wherein each of the first area, the second area, and the third area contains automated mechanism for servicing slots;
wherein, from the first area and the third area, slots are serviced from fronts of the slots, where servicing comprises moving a device into, or out of, a front of a slot; and
wherein, from the second area, slots are serviced from backs of the slots, where servicing comprises moving a device into, or out of, a back of a slot.

19. The method of claim 17, wherein a front of a double-sided slot and a back of a double-sided slot are serviced asynchronously, where servicing comprises moving a device into, or out of, the front of the double-sided slot or the back of the double-sided slot.

20. The method of claim 12, wherein the air mover and the heat exchanger are arranged serially in a column of the first rack or a column of the second rack.

21. The method of claim 12, wherein, in the column, the air mover is closer to the warm air than is the heat exchanger, and the heat exchanger is closer to cold air than is the air mover.

22. The method of claim 12, wherein the heat exchanger is a first heat exchanger and the air mover is a first air mover; and
wherein additional heat exchangers and air movers arranged together serially and in columns in both the first rack and the second rack.
